(19) United States
(12) Patent Application Publication
(10) Pub. No.: US 2012/0132264 A1
(43) Pub. Date: May 31, 2012

(54) SOLAR CELL AND METHOD FOR FABRICATING THE SAME

(75) Inventors: Chien-Hsun Chen, Tainan City (TW); Yu-Ru Chen, Taichung City (TW)

(73) Assignee: INDUSTRIAL TECHNOLOGY RESEARCH INSTITUTE, Hsinchu (TW)

(21) Appl. No.: 13/018,370

(22) Filed: Jan. 31, 2011

(30) Foreign Application Priority Data
Nov. 30, 2010 (TW) 99141512

(51) Int. Cl. H01L 31/072; H01L 31/02

(52) U.S. Cl. 136/255; 438/57; 257/E31.11

(57) ABSTRACT

A solar cell and a method for fabricating the same are described. A pyramid structure is formed on a silicon substrate. A laser treatment is performed on the pyramid structure, so that a top portion of the pyramid structure has an arc shape, and a round is formed at a crest line of the pyramid structure. Films formed during subsequent processes hence have a uniform thickness and conversion efficiency of the solar cell is improved.

### CROSS-REFERENCE TO RELATED APPLICATION

This application claims the priority benefit of Taiwan application serial no. 99141512, filed on Nov. 30, 2010. The entirety of the above-mentioned patent application is hereby incorporated by reference herein and made a part of this specification.

### BACKGROUND OF THE INVENTION

1. Field of the Invention

The disclosure is related to a photoelectric device, and in particular to a solar cell which enhances photoelectric conversion efficiency and a method for fabricating the same.

2. Description of Related Art

Solar energy is a type of inexhaustible and non-pollutive energy and is receiving the most attention when it comes to solving the pollution and shortage faced by fossil fuels. Solar cells are able to directly convert solar energy into electricity and are hence currently an important research topic.

Silicon-based solar cells are a common type of solar cells in the industry. The principle of silicon-based solar cells is that a semiconductor material (silicon) of high purity is doped with some impurities so that different characteristics are displayed, so as to form a P type semiconductor and an N type semiconductor. The P type and N type semiconductors are bonded, thereby forming a p-n junction. The p-n junction is formed by positively charged donor ions and negatively charged acceptor ions. In an area where the positive and negative ions are located, a built-in potential exists. The built-in potential drives mobile carriers in this area, so that this area is termed a depletion region. When sunlight irradiates on a semiconductor which has a p-n structure, energy provided by photons excite electrons in the semiconductor, generating electron-hole pairs. The electrons and holes are both affected by the built-in potential, the holes move towards a direction of an electric field, and the electrons move towards the opposite direction. If a wire is used to connect the solar cell and a load, so as to form a loop, a current flows through a load. The above is the mechanism of generating electricity with a solar cell. If solar cells are to be improved, the best place to start with is their photoelectric conversion efficiency.

Silicon substrates of silicon-based solar cells with heterogeneous junctions usually have sharp and protruding pyramid structures to reduce reflective ratios and increase photocurrents. However, if an angle of the pyramid structures is too small and a crest line is too sharp, subsequent film formation process are easily affected, so that films that are formed are likely to have problems of non-uniform thickness and may even become broken through, thereby causing short circuits.

In order to solve the above problems, the industry currently proposes a method for performing a post-etching process after forming the pyramid structures on the surface of the silicon substrate, so as to remove acute angles at bottom portions of the pyramid structures, and performing the subsequent film coating processes (such as that described in U.S. Pat. No. 6,380,479). However, if the etching process is used to remove the acute angles at the bottom portions of the pyramid structures, angles at top portions of the pyramid structures are also increased, thereby increasing the reflective ratios and reducing photocurrents.

### SUMMARY OF THE INVENTION

In light of the above, the disclosure provides a solar cell and a method for fabricating the same. By using laser ablation to modify a surface structure of a silicon substrate, uniformity of deposited films is increased, and device conversion efficiency is enhanced.

The disclosure provides a solar cell which includes a silicon substrate and a first semiconductor layer. A first surface of the silicon substrate has a pyramid structure, a top portion of the pyramid structure has an arc shape, and a round is formed at a crest line of the pyramid structure. A first semiconductor layer is disposed on the first surface of the silicon substrate, wherein a conductive type of the first semiconductor layer is opposite to a conductive type of the silicon substrate.

The disclosure provides a method for fabricating a solar cell which includes the following steps. A silicon substrate is provided, and a pyramid structure is formed on a first surface of the silicon substrate. A laser treatment is performed, so that a top portion of the pyramid structure has an arc shape, and a round is formed at a crest line of the pyramid structure. A first semiconductor layer is formed on the first surface of the silicon substrate.

Due to the above, since in the solar cell and the method for fabricating the same according to the disclosure, the pyramid structure whose top portion has the arc shape and whose crest line has the round is formed on the surface of the silicon substrate, subsequent film coating problems are able to be solved with the minimum impact on light absorption.

Moreover, since the laser treatment is used to form the above pyramid structure, by controlling the focusing position, energy, and irradiation time of the laser, the structures at different positions such as the top portion or the bottom portion of the pyramid structure are altered, thereby simplifying the process of controlling the contour of the pyramid structure without losing light trapping abilities. Therefore, the method for fabricating the solar cell according to the disclosure is simple and adjustable.

In order to make the aforementioned and other objects, features and advantages of the disclosure comprehensible, embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional diagram illustrating a solar cell according to an embodiment of the disclosure.

FIG. 2 is a schematic cross-sectional diagram illustrating a silicon substrate according to an embodiment of the disclosure.

FIG. 3A is a photograph illustrating a top of a silicon substrate according to an embodiment of the disclosure.

FIG. 3B is a photograph illustrating a cross-section of a silicon substrate according to an embodiment of the disclosure.

FIG. 4 is a schematic cross-sectional diagram illustrating a solar cell according to an embodiment of the disclosure.

FIGS. 5A to 5C are schematic cross-sectional diagrams illustrating a method for fabricating a solar cell according to an embodiment of the disclosure.

FIG. 6A is a photograph illustrating a top of a silicon substrate prior to any laser treatment.

FIG. 6B is a photograph illustrating a cross-section of a silicon substrate prior to any laser treatment.

FIG. 7 is a diagram illustrating curves which represent wavelengths versus reflective ratios according to a comparative embodiment and experimental embodiments 1 to 3.

### DESCRIPTION OF EMBODIMENTS

The following description is supplemented by accompanying drawings to be illustrated more fully. However, the disclosure may be implemented in multiple different manners and is not limited to the embodiments described herein. In the following embodiments, terms that indicate directions, such as “above” and “below” are used in reference to directions in the accompanying drawings and are hence used for description but not for limiting the disclosure. For the sake for clarity, sizes and relative sizes of each layer shown in the drawings may be exaggerated.

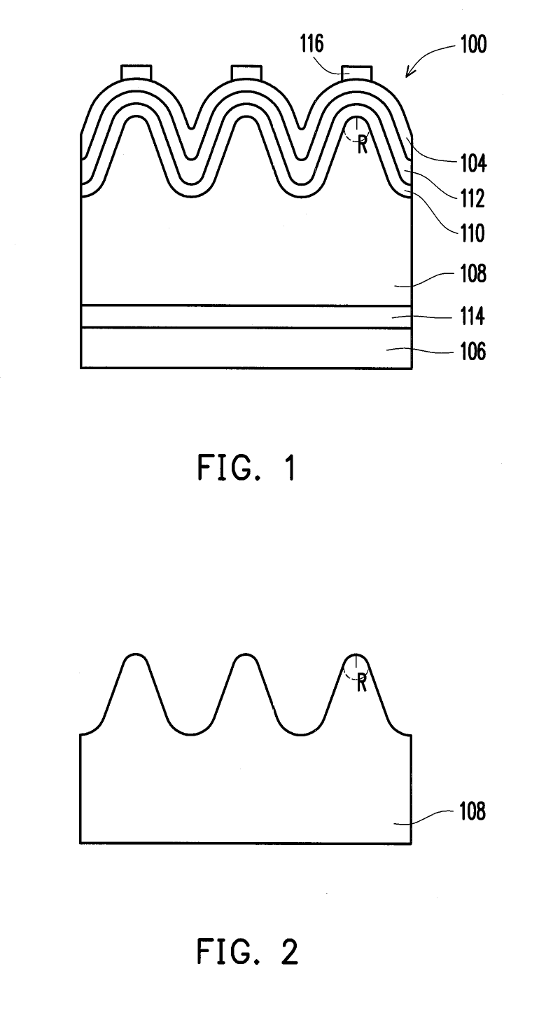

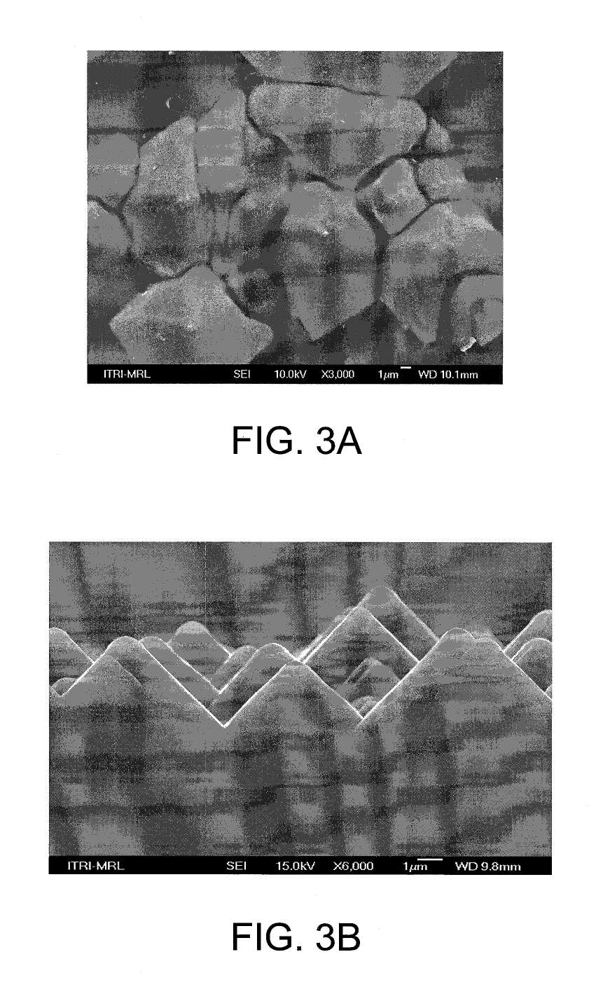

FIG. 1 is a schematic cross-sectional diagram illustrating a solar cell according to an embodiment of the disclosure. FIG. 2 is a schematic cross-sectional diagram illustrating a silicon substrate according to an embodiment of the disclosure. FIG. 3A is a photograph illustrating a top of a silicon substrate according to an embodiment of the disclosure. FIG. 3B is a photograph illustrating a cross-section of a silicon substrate according to an embodiment of the disclosure.

Please refer to FIG. 1, a solar cell 100 includes, for example, a first electrode 104, a second electrode 106, a first conductive type silicon substrate 108, an intrinsic layer 110, and a second conductive type semiconductor layer 112.

A material of the first conductive type silicon substrate 108, the intrinsic layer 110, and the second conductive type semiconductor layer 112 is, for example, silicon or a multiple-layer structure of stacked alloys thereof. The above silicon includes single crystal silicon, polycrystal silicon, amorphous silicon, or microcrystal silicon. The above silicon alloy includes silicon doped with hydrogen atoms, fluorine atoms, chlorine atoms, germanium atoms, oxygen atoms, carbon atoms, or nitrogen atoms.

According to the present embodiment, a conductive type of the second conductive type semiconductor layer 112 is opposite to a conductive type of the first conductive type silicon substrate 108. For example, when the first conductive type is N type, the second conductive type is P type; when the second conductive type is N type, the first conductive type is P type. According to another embodiment, the intrinsic layer 110 may be omitted from the solar cell 100. The P type semiconductor layer is doped with group IIIA elements of the periodic table of elements, such as boron, gallium, and indium. The N type semiconductor layer is doped with group VA elements of the periodic table of elements, such as phosphorus, arsenic, and antimony.

Please refer to FIGS. 2, 3A, and 3B. A surface of the first conducive type silicon substrate 108 has a pyramid structure. In detail, an uneven surface with the pyramid structure increases a chance that sunlight is scattered in the solar cell and decreases reflection of incident light, so that a travel distance of incident light in a photoelectric conversion layer is increased, thereby enhancing absorption of photons and providing more electron-hole pairs. According to the present embodiment, a top portion of the pyramid structure has an arc shape, and a round is formed at a crest line of the pyramid structure. A radius of curvature 1/R at the top portion of the pyramid structure is less than a radius of curvature at a bottom portion of the pyramid structure. The radius of curvature 1/R at the top portion of the pyramid structure is from 0.01 μm⁻¹ to 1 μm⁻¹. The second conductive type semiconductor layer 112 is disposed on the surface of the first conductive type silicon substrate 108 on which the pyramid structure is formed.

The first electrode 104 is, for example, disposed on the entire surface of the second conductive type semiconductor layer 112. A material of the first electrode 104 may be a transparent conductive oxide (TCO), such as zinc oxide (ZnO), indium oxide (In₂O₃), tin dioxide (SnO₂), indium tin oxide (ITO), indium zinc oxide (IZO), aluminum tin oxide (ATO), aluminum doped zinc oxide (AZO), cadmium indium oxide (CIO), cadmium zinc oxide (CZO), gallium doped zinc oxide (GZO), indium tin zinc oxide (ITZO), indium-gallium-zinc oxide (IGZO), zinc-tin oxide (ZTO), fluorine doped tin oxide (FTO), or a combination of the above materials.

Comb electrodes 116 are disposed on the first electrode 104. A material of the comb electrodes 116 is, for example, a metal. The above metal is, for example, aluminum, silver, molybdenum, or copper.

The second electrode 106 is, for example, disposed on a back surface of the first conductive type silicon substrate 108. A material of the second electrode 106 is, for example, a metal or a transparent conductive oxide. The above transparent conductive oxide is, for example, zinc oxide, indium oxide, tin dioxide, indium tin oxide, indium zinc oxide, aluminum tin oxide, aluminum doped zinc oxide, cadmium indium oxide, cadmium zinc oxide, gallium doped zinc oxide, indium tin zinc oxide, indium-gallium-zinc oxide, zinc-tin oxide, fluorine doped tin oxide, or a combination of the above materials. The above metal is, for example, aluminum, silver, molybdenum, copper, or an alloy of the above metals.

In addition, in order to prevent effects generated by recombination of carriers near the back surface of the first conductive type silicon substrate 108, a first conductive type highly doped layer 114 is disposed between the first conductive type silicon substrate 108 and the second electrode 106, so as to form a so-called back surface field (BSF) type solar cell which induces an internal electric field. A dopant concentration of the first conductive type highly doped layer 114 is greater than that of the first conductive type silicon layer.

According to the present embodiment, since the pyramid structure whose top portion has an arc shape and whose crest line has a round is formed on the surface of the first conductive type silicon substrate 108, subsequent film coating problems are able to be solved with the minimum impact on light absorption.

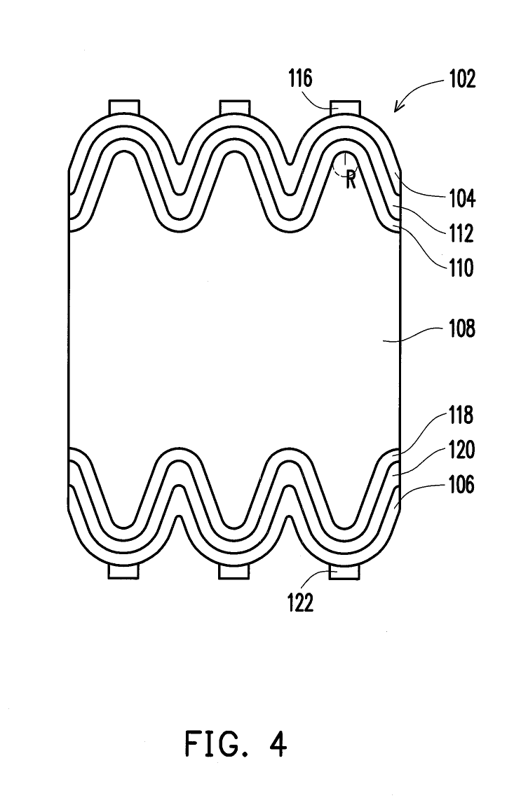

FIG. 4 is a schematic cross-sectional diagram illustrating a solar cell according to an embodiment of the disclosure. In FIG. 4, the same reference numerals as those in FIG. 1A represent the same elements and are not repeatedly described.

Please refer to FIG. 4. A solar cell 102 includes, for example, the first electrode 104, the second electrode 106, the first conductive type silicon substrate 108, the intrinsic layer 110, the second conductive type semiconductor layer 112, an intrinsic layer 118, and a second conductive type semiconductor layer 120.

A material of the first conductive type silicon substrate 108, the intrinsic layer 110, the second conductive type semiconductor layer 112, the intrinsic layer 118, the second conductive type semiconductor layer 120 is, for example, silicon or a multiple-layer structure of stacked alloys thereof. The above silicon includes single crystal silicon, polycrystal silicon, amorphous silicon, or microcrystal silicon. The above silicon alloy includes silicon doped with hydrogen atoms, fluorine atoms, chlorine atoms, germanium atoms, oxygen atoms, carbon atoms, or nitrogen atoms.

According to the present embodiment, a conductive type of the second conductive type semiconductor layer 112 and the second conductive type semiconductor layer 120 is opposite to the conductive type of the first conductive type silicon substrate 108. For example, when the first conductive type is N type, the second conductive type is P type; when the second conductive type is N type, the first conductive type is P type. The P type semiconductor layer is doped with group IIIA elements of the periodic table of elements, such as boron, gallium, and indium. The N type semiconductor layer is doped with group VA elements of the periodic table of elements, such as phosphorus, arsenic, and antimony. According to another embodiment, the intrinsic layer 110 and the intrinsic layer 118 may be omitted from the solar cell 100.

Each of a first surface and a second surface (which are opposite to each other) of the first conductive type silicon substrate 108 has a pyramid structure, a top portion of the pyramid structure has an arc shape, and a round is formed at a crest line of the pyramid structure. A radius of curvature 1/R at the top portion of the pyramid structure is less than a radius of curvature at a bottom portion of the pyramid structure. The radius of curvature 1/R at the top portion of the pyramid structure is from 0.01 μm⁻¹ to 1 μm⁻¹, and a radius of curvature at the round of the crest line thereof is from 0.01 μm⁻¹ to 1 μm⁻¹. The second conductive type semiconductor layer 112 is disposed on the first surface of the first conductive type silicon substrate 108. The second conductive type semiconductor 120 is disposed on the second surface of the first conductive type silicon substrate 108.

The first electrode 104 is, for example, disposed on the surface of the second conductive type semiconductor layer 112. A material of the first electrode 104 may be a transparent conductive oxide such as zinc oxide, indium oxide, tin dioxide, indium tin oxide, indium zinc oxide, aluminum tin oxide, aluminum doped zinc oxide, cadmium indium oxide, cadmium zinc oxide, gallium doped zinc oxide, indium tin zinc oxide, indium-gallium-zinc oxide, zinc-tin oxide, fluorine doped tin oxide, or a combination of the above materials.

The comb electrodes 116 are disposed on the first electrode 104. A material of the comb electrodes 116 is, for example, a metal. The above metal is, for example, aluminum, silver, molybdenum, or copper.

The second electrode 106 is, for example, disposed on a surface of the second conductive type semiconductor layer 120. A material of the second electrode 106 may be a transparent conductive oxide such as zinc oxide, indium oxide, tin dioxide, indium tin oxide, indium zinc oxide, aluminum tin oxide, aluminum doped zinc oxide, cadmium indium oxide, cadmium zinc oxide, gallium doped zinc oxide, indium tin zinc oxide, indium-gallium-zinc oxide, zinc-tin oxide, fluorine doped tin oxide, or a combination of the above materials.

Comb electrodes 122 are disposed on the second electrode 106. A material of the comb electrodes 122 is, for example, a metal. The above metal is, for example, aluminum, silver, molybdenum, or copper.

According to the present embodiment, since the pyramid structure whose top portion has the arc shape and whose crest line has the round is formed on each of the first surface and the second surface of the first conductive type silicon substrate 108, subsequent film coating problems are able to be solved with the minimum impact on light absorption.

Next, a method for fabricating the solar cell according to the disclosure is described. The solar cell in FIG. 4 is shown as an example.

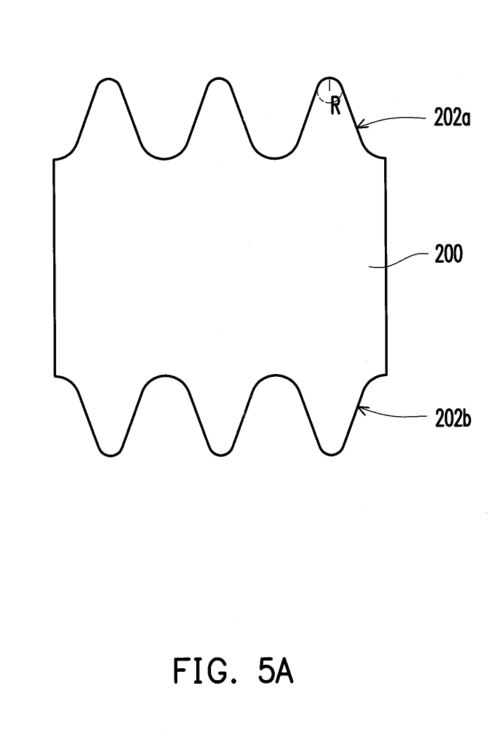

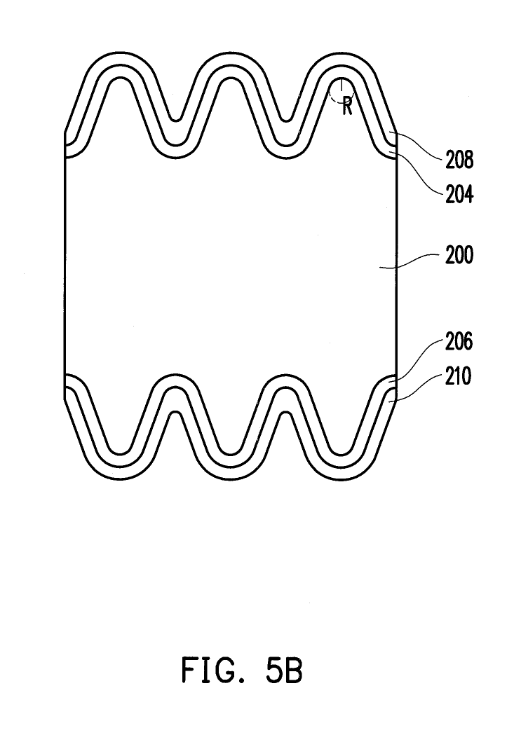

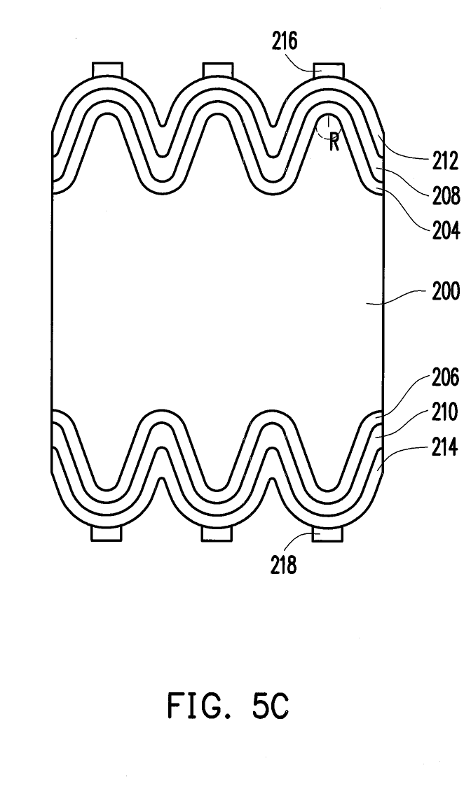

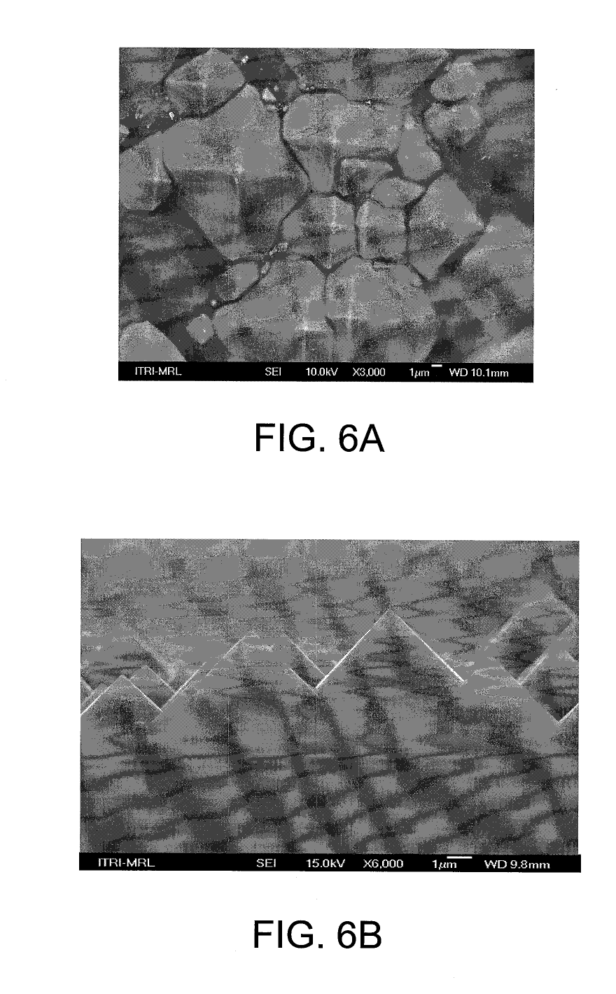

FIGS. 5A to 5C are schematic cross-sectional diagrams illustrating a method for fabricating a solar cell according to an embodiment of the disclosure. FIG. 6A is a photograph illustrating a top of a silicon substrate prior to any laser treatment. FIG. 6B is a photograph illustrating a cross-section of a silicon substrate prior to any laser treatment.

Please refer to FIG. 5A. A first conductive type silicon substrate 200 is provided. Next, a pyramid structure 202a is formed on a first surface of the first conductive type silicon substrate 200, and a pyramid structure 202b is formed on a second surface of the first conductive type silicon substrate 200 (as shown in FIGS. 6A and 6B). A method for forming the pyramid structure 202a and the pyramid structure 202b is, for example, performing an anisotropic etching process. A height of the pyramid structure 202a and the pyramid structure 202b is, for example, from 5 μm to 15 μm, and a top angle of the pyramid structure 202a and the pyramid structure 202b is, for example, from 70 degrees to 80 degrees. An etching solution used in the anisotropic etching process is, for example, an aqueous solution of sodium hydroxide (NaOH) and isopropanol.

Afterwards, a laser treatment is performed, so that a top portion of the pyramid structure has an arc shape, and a round is formed at a crest line of the pyramid structure (as shown in FIGS. 3A and 3B). A radius of curvature 1/R at the top portion of the pyramid structure is less than a radius of curvature at a bottom portion of the pyramid structure. The radius of curvature 1/R at the top portion of the pyramid structure is from 0.01 μm⁻¹ to 1 μm⁻¹, and a radius of curvature at the round of the crest line thereof is from 0.01 μm¹ to 1 μm⁻¹.

During the laser treatment, operation conditions are as follows.

A wave length of a laser: 200 nm to 1200 nm
A focusing height: −13.58 mm to −14.6 mm
A beam size of the laser: 20 μm to 60 μm
An energy intensity of the laser: 0.1 J/m² to 5 J/m²
A speed of a carrying platform: 50 mm/sec to 300 mm/sec

Please refer to FIG. 5B. An intrinsic layer 204 is formed on the first surface of the substrate 200, and an intrinsic layer 206 is formed on the second surface of the substrate 200. A method for forming the intrinsic layer 204 and the intrinsic layer 206 is, for example, a plasma-enhanced chemical vapor deposition method. During the process of forming the intrinsic layer 204 and the intrinsic layer 206, silane (SiH₄) is used as a reactive gas.

Next, a second conductive type semiconductor layer 208 is formed on the intrinsic layer 204, and a second conductive type semiconductor layer 210 is formed on the intrinsic layer 206. The second conductive type semiconductor layer 208 and the second conductive type semiconductor layer 210 are formed by, for example, using in-situ doping with a plasma-enhanced chemical vapor deposition method. During the process of forming the second conductive type semiconductor layer 208 and the second conductive type semiconductor layer 210, silane (SiH₄) is used as a reactive gas, and at the same time, according to a type of a dopant to be implanted, a compound which contains the dopant is used as a dopant gas.

Please refer to FIG. 5C, a first electrode 212 is formed on the second conductive type semiconductor layer 208, and a second electrode 214 is formed on the second conductive type semiconductor layer 210. A material of the first electrode 212 and the second electrode 214 may be a transparent conductive oxide. According to an embodiment, a method for forming the first electrode 212 and the second electrode 214 may be sputtering, metal organic chemical vapor deposition (MOCVD), evaporation, or spraying.

Comb electrodes 216 are formed on the first electrode 212, and comb electrodes 218 are formed on the second electrode 214. A material of the comb electrodes 216 and the comb electrodes 218 is, for example, a metal, a transparent conductive oxide (TCO), or a combination of a metal and a transparent conductive oxide.

In the method for fabricating the solar cell according to the disclosure, laser ablation is used to modify the contour of the pyramid structure, so that a top portion of the pyramid structure has an arc shape, and a round is formed at a crest line of the pyramid structure, thereby enhancing uniformity of subsequently deposited films and increasing device conversion efficiency.

In addition, the laser treatment is more simple than conventional acid and alkaline etching or plasma etching and reduces pollution.

Moreover, by changing different laser operation parameters, surface structures of the silicon substrate are altered. By controlling the focusing position, energy, and irradiation time of the laser, the structures at different positions such as the top portion or the bottom portion of the pyramid structure are altered, thereby simplifying the process of controlling the contour of the pyramid structure. By utilizing the characteristics of tunable focus and power, the curvature of the pyramid is controlled, so that light trapping abilities are not lost. Therefore, the method for fabricating the solar cell according to the disclosure is simple and adjustable.

The following describes experimental embodiments to further describe the solar cell and the fabricating method thereof.

### Examples 1 to 3

After forming the pyramid structure on the silicon substrate, the laser treatment is performed on the silicon substrate. The parameters for the laser treatment are as follows.

The wave length of the laser: 532 nm
The focusing height: −14.6 mm
The size of the light beam: 50 nm
The energy intensity: 2 J/m² (example 1), 2.25 J/m² (example 2), 2.5 J/m² (example 3)
The speed of the carrying platform: 100 mm/sec

### Comparative Example

The pyramid structure is formed on the silicon substrate, but no laser treatment is performed.

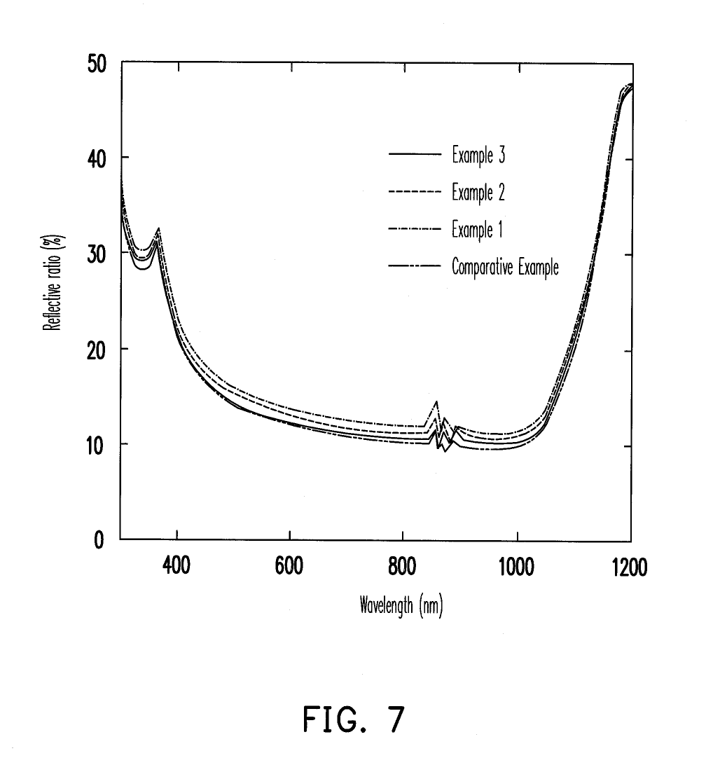

Next, radii of curvature and reflective ratios at the top portions of the pyramid structures in the comparative example and the examples 1 to 3 are measured. The radii of curvature and reflective ratios at the top portions of the pyramid structures in the comparative example and the examples 1 to 3 are 0.1 μm⁻¹, 0.4 μm⁻¹, 0.6 μm⁻¹, and 0.8 μ⁻¹, respectively. The reflective ratios in the comparative example and examples 1 to 3 are shown in FIG. 7.

According to FIG. 7, the reflective ratios in the examples 1 to 3 are not significantly worse than the reflective ratio in the comparative example. Therefore, the arced pyramid structure which has been processed by the laser treatment according to the disclosure is able to retain its light capturing ability and output of photocurrents without altering an angle of a main body.

In light of the above, in the solar cell according to the disclosure, since the pyramid structure whose top portion has the arc shape and whose crest line has the round is formed on the substrate, subsequent film coating problems are able to be solved with the minimum impact on light absorption, thereby enhancing uniformity of deposited films and device conversion efficiency.

In the method for fabricating the solar cell according to the disclosure, the laser ablation is used to modify the contour of the pyramid structure of the silicon substrate. The laser treatment is more simple than conventional acid and alkaline etching or plasma etching and reduces pollution. Furthermore, the method for fabricating the solar cell according to the disclosure is simple and adjustable.

It will be apparent to those skilled in the art that various modifications and variations can be made to the disclosure without departing from the scope or spirit of the disclosure. In view of the foregoing, it is intended that the disclosure cover modifications and variations of this disclosure provided they fall within the scope of the following claims and their equivalents.

What is claimed is:

1. A solar cell, comprising:
a silicon substrate, wherein a first surface of the silicon substrate has a pyramid structure, a top portion of the pyramid structure has an arc shape, and a round is formed at a crest line of the pyramid structure; and
a first semiconductor layer, disposed on the first surface of the silicon substrate, wherein a conductive type of the first semiconductor layer is opposite to a conductive type of the silicon substrate.

2. The solar cell as claimed in claim 1, wherein a radius of curvature at the top portion of the pyramid structure is less than a radius of curvature at a bottom portion of the pyramid structure.

3. The solar cell as claimed in claim 1, wherein the radius of curvature at the top portion of the pyramid structure is from 0.01 μm⁻¹ to 1 μm⁻¹.

4. The solar cell as claimed in claim 1, wherein a radius of curvature at the round of the crest line of the pyramid structure is from 0.01 μm⁻¹ to 1 μm⁻¹.

5. The solar cell as claimed in claim 1, further comprising an intrinsic layer, disposed between the first semiconductor layer and the silicon substrate.

6. The solar cell as claimed in claim 1, wherein a material of the first semiconductor layer comprises amorphous silicon or microcrystal silicon.

7. The solar cell as claimed in claim 1, wherein the second surface of the silicon substrate has the pyramid structure, the top portion of the pyramid structure has the arc shape, the round is formed at the crest line of the pyramid structure, and the second surface is opposite to the first surface.

8. The solar cell as claimed in claim 7, wherein a radius of curvature at the top portion of the pyramid structure is less than a radius of curvature at a bottom portion of the pyramid structure.

9. The solar cell as claimed in claim 8, wherein the radius of curvature at the top portion of the pyramid structure is from 0.01 μm⁻¹ to 1 μm⁻¹.

10. The solar cell as claimed in claim 8, wherein a radius of curvature at the round of the crest line of the pyramid structure is from 0.01 μm⁻¹ to 1 μm⁻¹.

11. The solar cell as claimed in claim 7, further comprising a second semiconductor layer, disposed on the second surface of the silicon substrate, wherein a conductive type of the second semiconductor layer is opposite to the conductive type of the silicon substrate.

12. The solar cell as claimed in claim 11, further comprising a second intrinsic layer, disposed between the second semiconductor layer and the silicon substrate.

13. A method for fabricating a solar cell, comprising:
providing a silicon substrate;
forming a pyramid structure on a first surface of the silicon substrate;
performing a laser treatment, so that a top portion of the pyramid structure has an arc shape, and a round is formed at a crest line of the pyramid structure; and
forming a first semiconductor layer on the first surface of the silicon substrate.

14. The method for fabricating the solar cell as claimed in claim 13, wherein a radius of curvature at the top portion of the pyramid structure is less than a radius of curvature at a bottom portion of the pyramid structure.

15. The method for fabricating the solar cell as claimed in claim 13, wherein the radius of curvature at the top portion of the pyramid structure is from 0.01 μm⁻¹ to 1 μm⁻¹.

16. The method for fabricating the solar cell as claimed in claim 13, wherein a radius of curvature at the round of the crest line of the pyramid structure is from 0.01 μm⁻¹ to 1 μm⁻¹.

17. The method for fabricating the solar cell as claimed in claim 13, wherein a method for forming the pyramid structure on at least the first surface of the silicon substrate comprises an anisotropic etching process.

18. The method for fabricating the solar cell as claimed in claim 13, further comprising forming the pyramid structure on a second surface of the silicon substrate, wherein the second surface is opposite to the first surface.

19. The method for fabricating the solar cell as claimed in claim 13, wherein during the laser treatment process, a wavelength of a laser is from 355 nm to 532 nm.

20. The method for fabricating the solar cell as claimed in claim 13, wherein during the laser treatment process, a focusing height is from −13.58 mm to −14.6 mm.

21. The method for fabricating the solar cell as claimed in claim 13, wherein during the laser treatment process, a beam size of a laser is from 20 μm to 60 μm.

22. The method for fabricating the solar cell as claimed in claim 13, wherein during the laser treatment process, an energy density of a laser is from 0.1 J/m² to 5 J/m².

23. The method for fabricating the solar cell as claimed in claim 13, wherein during the laser treatment process, a speed of a carrying platform is from 50 mm/sec to 300 mm/sec.
